(19) United States
(12) Patent Application Publication
(10) Pub. No.: US 2025/0171917 A1
(43) Pub. Date: May 29, 2025

(54) DEFECT-RICH MOS2 MONOLAYER, METHODS FOR PRODUCING THE SAME AND USES THEREOF

(71) Applicant: CITY UNIVERSITY OF HONG KONG, Kowloon (HK)

(72) Inventors: Thuc Hue LY, Kowloon (HK); Ping MAN, Kowloon (HK); Ka Ho LEUNG, Kowloon (HK)

(21) Appl. No.: 18/522,053

(22) Filed: Nov. 28, 2023

(51) Int. Cl. C25B 11/075; C25B 1/04; C25B 11/055

(52) U.S. Cl. CPC C25B 11/075; C25B 1/04; C25B 11/055

(57) ABSTRACT

Disclosed herein are a defect-rich molybdenum disulfide (MoS₂) monolayer, its production method and uses thereof. The defect-rich MoS₂ monolayer is characterized in having a vacancy density up to 3.35×10¹⁴/cm², and is produced by vapor deposition on a substrate in the presence of potassium chloride (KCl). The defect-rich MoS₂ monolayer could serve as an electrocatalyst in hydrogen evolution reaction (HER) to convert proton into hydrogen. Also disclosed herein is a MoS₂-based microelectroactalysis cell, which is a three-electrode system, comprising a working electrode, a counter electrode, a reference electrode and an electrolyte; in which the working electrode, the counter electrode or both independently comprises the vacancy-rich MoS₂ monolayer coated thereon.

### BACKGROUND OF THE INVENTION

### 1. Field of the Invention

The present disclosure in general relates to the field of MoS₂ defect engineering and method for manufacturing the same.

### 2. Description of Related Art

The green hydrogen energy produced from electrochemical water splitting promises to develop highly active low-cost electrocatalysts with the most abundant resources on earth. 2D transition metal dichalcogenides (TMDs), especially the direct band gap semiconductors such as molybdenum disulfide (MoS₂) show superior mass and electron transport capabilities, making them a promising alternative to noble metal catalysts for hydrogen evolution reaction (HER). Early studies show that the catalytic site of MoS₂ for HER is mainly concentrated in the atomically thin active edges, rather than on the large area basal planes. Then, the following developments on MoS₂ HER catalysts all took this as a guiding principle—to maximize the active edge sites, or to activate the originally inert basal plane sites which occupy a significantly higher percentage.

Defects have been extensively studied and utilized as a distinct category of catalytic active sites, as they can increase the exposure of catalytic active sites and turn the electronic structures to improve intrinsic activity. Defect engineering in 2D TMDs is usually achieved by heterogenous atom doping or vacancy creation. A variety of strategies, such as hydrogen plasma exposure, H₂ annealing, Ar²⁺ beam irradiation, and helium ion beam irradiation have been successfully implemented to introduce vacancies in 2D TMDs. However, all of the afore-mentioned technologies require external stimuli for additional intervention, and the generation of controllable vacancies directly by growth remains a challenging task.

Accordingly, there exists in the related art a need of an improved method for introducing vacancies into the inert basal plane of MoS₂ monolayer in a controllable manner. The improved method as disclosed herein is easy-to-use, and the MoS₂ monolayer thus produced has high density of vacancy defects on the basal plane of 2D MoS₂, thus is suitable for many applications (e.g., an electrocatalyst in hydrogen evolution reaction (HER)).

### SUMMARY OF THE INVENTION

The present disclosure provides a novel method for producing a defect-rich molybdenum disulfide (MoS₂) monolayer suitable for use as an electrocatalyst in hydrogen evolution reaction (HER). Preferably, the defect-rich MoS₂ monolayer acting as an electrocatalyst may be used as an electrode (e.g., a working electrode, a counter electrode, and/or a reference electrode) in a MoS₂-based microelectroactalysis cell (e.g., hydrogen fuel cell) to convert protons into hydrogen (H₂).

Accordingly, there is provided a method for producing a defect-rich MoS₂ monolayer by vapor depositing the MoS₂ monolayer in the presence of potassium chloride (KCl), and the MoS₂ monolayer is characterized in having a vacancy density up to 3.35×10¹⁴/cm².

According to embodiments of the present disclosure, the MoS₂ monolayer is vapor deposited by:
(a) spraying a solution of the KCl on a growth substrate disposed in a reaction chamber; and
(b) allowing a sulfur precursor to react with a molybdenum precursor at about 800-840° C. in a flow of a carry gas for about 10-20 mins to deposit the MoS₂ monolayer on the growth substrate.

According to embodiments of the present disclosure, in step (a), the KCl solution is about 0.5 to 3.0 M in concentration. Preferably, the KCl solution is about 2.0 M in concentration; more preferably, about 2.5 M in concentration.

Examples of the sulfur precursor suitable for use in step (b) of the present method include, but are not limited to, sulfur powder, hydrogen sulfide (H₂S), dialkyl disulfide, dihalo disulfide and the like.

Examples of the molybdenum precursor suitable for use in step (b) of the present method include, but are not limited to, sodium molybdate dihydrate (Na₂MoO₄·2H₂O), molybdenum hexafluoride (MoF₆), molybdenum hexachloride (MoCl₆) and molybdenum hexacarbonyl (Mo(CO)₆).

Examples of the carry gas suitable for use in step (b) of the present method include, but are not limited to, argon (Ar), nitrogen (N₂) and the like.

According to preferred embodiments of the present disclosure, in step (b), sulfur powder and sodium molybdate dihydrate are reacted at about 800-840° C. under 200 sccm Ar for 10-20 mins to deposit a monolayer of MoS₂ on the growth substrate, which is termed “the MoS₂ growth substrate (e.g., silicon dioxide)”.

According to optional embodiments of the present disclosure, the MoS₂ monolayer thus formed may be transferred to a target substrate, such as an electrode of a hydrogen fuel cell, for further use. Accordingly, the method further comprises steps of,
(c) spin-coating a polymethyl-methacrylate (PMMA) solution on the MoS₂ monolayer to form a PMMA/MoS₂ growth substrate;
(d) immersing the PMMA/MoS₂ growth substrate in an alkaline solution to detach the PMMA/MoS₂ structure from the growth substrate;
(e) transferring the detached PMMA/MoS₂ structure onto a target substrate thereby forming a PMMA/MoS₂ target substrate; and
(f) washing the PMMA/MoS₂ target substrate with one or more solvent to remove the PMMA layer thereby transferring the MoS₂ monolayer onto the target substrate.

According to embodiments of the present disclosure, in step (c), PMMA solution is spin-coated onto the MoS₂ monolayer at a speed of 3,000 rpm for about 60 seconds thereby forming a PMMA/MoS₂ growth substrate.

According to embodiments of the present disclosure, in step (d), the alkaline solution may be a solution of potassium hydroxide (KOH) or sodium hydroxide (NaOH). In one example, the PMMA/MoS₂ growth substrate is immersed in 0.5 M KOH solution at 75° C. for about 1-15 mins. In another example, the PMMA/MoS₂ growth substrate is immersed in 0.5 M NaOH solution at 75° C. for about 1-15 mins.

Examples of the solvent suitable for use in step (f) of the present method include, but are not limited to, acetone, isopropanol, ethanol and a combination thereof. According to one preferred embodiment of the present disclosure, in step (f), the PMMA/MoS₂ target substrate is washed in sequence with acetone, isopropanol, and ethanol.

According to embodiments of the present disclosure, the growth substrate may be made of silicon dioxide or silicon, and the target substrate may be a transmission electron microscopy (TEM) grid or a semi-conducting substrate made of a material selected from the group consisting of glass, carbon fiber, carbon nanotube, carbon cloth, graphene, indium tin oxide, silicon, titanium dioxide and titanium metal.

Also encompassed herein is a MoS₂-based microelectroactalysis cell characterized in having a MoS₂ monolayer produced by the present method that serves as an electrocatalyst for hydrogen evolution reaction. The MoS₂-based microelectroactalysis cell comprises a working electrode, a counter electrode, a reference electrode, and an electrolyte; in which the working electrode, the counter electrode or both independently comprises the present MoS₂ monolayer deposited thereon, and the MoS₂ monolayer has a vacancy density up to 3.35×10¹⁴/cm².

According to embodiments of the present disclosure, the defect-rich MoS₂ monolayer is produced by a method comprising:
(a) spraying a KCl solution on a growth substrate disposed in a reaction chamber;
(b) allowing a sulfur precursor to react with a molybdenum precursor at about 800-840° C. in a flow of a carry gas for about 10-20 mins to deposit the MoS₂ monolayer on the growth substrate;
(c) spin-coating a polymethyl-methacrylate (PMMA) solution on the MoS₂ monolayer to form a PMMA/MoS₂ growth substrate;
(d) immersing the PMMA/MoS₂ growth substrate in an alkaline solution to detach the PMMA/MoS₂ structure from the growth substrate;
(e) transferring the detached PMMA/MoS₂ structure onto a target substrate thereby forming a PMMA/MoS₂ target substrate; and
(f) washing the PMMA/MoS₂ target substrate with one or more solvent to remove the PMMA layer thereby transferring the MoS₂monolayer onto the target substrate;
wherein, the target substrate is the working electrode and/or the counter electrode of the MoS₂-based microelectroactalysis cell.

A further aspect of the present disclosure is therefore directed to a method for producing hydrogen from an aqueous solution via use of the MoS₂-based microelectroactalysis cell described above.

According to embodiments of the present disclosure, the aqueous solution is water.

The details of one or more embodiments of this disclosure are set forth in the accompanying description below. Other features and advantages of the invention will be apparent from the detail descriptions, and from claims. It is to be understood that both the foregoing general description and the following detailed description are by examples, and are intended to provide further explanation of the invention as claimed.

### BRIEF DESCRIPTION OF THE DRAWINGS

The patent or application file contains at least one drawing executed in colors. Copies of this patent or patent application publication with color drawing(s) will be provided by the Office upon request and payment of the necessary fee.

The accompanying drawings, which are incorporated in and constitute a part of the specification, illustrate various example systems, methods and other exemplified embodiments of various aspects of the invention. The present description will be better understood from the following detailed description read in light of the accompanying drawings, where:

FIG. 1a-1b. Structure of KCl-induced MoS₂. AFM images and the corresponding line profiles of MoS₂ in the (a) absence or (b) presence of 2.5 M KCl in accordance with one embodiment of the present disclosure;

FIG. 2a-2b. Structure of pristine KCl-induced MoS₂. Raman (a) and PL (b) spectra of MoS₂ basal plane under various KCl concentration from 0.0 to 3.0 M. The inset shows the statistic results of PL intensity under each concentration (C_{KCl});

FIGS. 3a-3d. Atomic structure of MoS₂-based catalysts. (a) STEM image of pristine MoS₂-0.0, (b) STEM image of MoS₂-1.5, and corresponding image showing different types of atoms/vacancies, (c) HAADF intensity profiles along the corresponding dash line in (b), (d) Statistics of surface sulfur vacancies density (⋅), V_{S} (▴), and V_{2S} ( [symbol] ) of MoS₂ under different KCl concentrations. The density is related to the whole basal plane and the ratio is relative to all sulfur atoms in monolayer MoS₂;

FIG. 4. Strain-field mapping of MoS₂ grown with different KCl from high-resolution STEM images. Sulfur vacancy ratio are marked on high-resolution STEM images. The strain color scale of shear strain (E_{xy}) and rotation lattice (rotation-xy) (R_{xy}) ranges from −0.2 (blue) to +0.2 (yellow);

FIG. 5a-5b. Structure of KCl induced MoS₂ after wet transfer. Normalized Raman (a) and PL (b) spectra of wet-transferred MoS₂ grown with different KCl concentrations in accordance with one embodiment of the present disclosure;

FIG. 6a-6b. HER activity of the MoS₂-based micro-electrochemical devices. (a) LSV curves and corresponding (b) Tafel plots of the MoS₂—KCl microdevices in accordance with one embodiment of the present disclosure;

FIGS. 7a-7f. Morphology and structure characterization after electrochemical tests. (a) Optical microscope (OM) image of fabricated microdevice MoS₂-2.5, (b) OM image of microdevice MoS₂-2.5 after tests, Raman peak intensity map at (c) 386 cm⁻¹ (E_{2g}¹ mode) and (d) 404 cm⁻¹ (A_{1g} mode), (e) Raman and (f) PL spectra of MoS₂-2.5 before and after tests in accordance with one embodiment of the present disclosure;

FIG. 8. The HER performance of edge sites in pristine MoS₂ flake in accordance with one embodiment of the present disclosure; and

FIG. 9a-9b. The potential dependent TOF curves of MoS₂ under different KCl concentration in accordance with one embodiment of the present disclosure.

### DETAILED DESCRIPTION OF THE PREFERRED EMBODIMENTS

The detailed description provided below in connection with the appended drawings is intended as a description of the present disclosure and is not intended to represent the only forms in which the present disclosure may be constructed or utilized.

### 1. Definition

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in the respective testing measurements. Also, as used herein, the term “about” generally means within 10%, 5%, 1%, or 0.5% of a given value or range. Alternatively, the term “about” means within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the term “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques.

The singular forms “a”, “and”, and “the” are used herein to include plural referents unless the context clearly dictates otherwise.

As used herein, an electrocatalyst is a catalyst participating in electrochemical reactions and usually functioning at electrode surfaces or may be the electrode itself. The electrocatalyst assists in transferring electrons between the electrode and reactants, and/or facilitates an intermediate chemical transformation described by half-reactions. Like other catalysts, an electrocatalyst lowers the activation energy for a reaction without altering the reaction equilibrium.

As used herein, the term “hydrogen evolution reaction (HER)” refers to the cathodic reaction in electrochemical water splitting, in which proton is reduced to form hydrogen (i.e., 2H⁺+2 e⁻→H₂), a critical chemical reagent and fuel. The reduction of proton to H₂ usually requires the aid of a catalyst, such as platinum or the present vacancy-rich MoS₂ monolayer.

### 2. Method of Forming a Vacancy-Rich MoS₂ Monolayer

Molybdenum disulfide (MoS₂) in its nanoparticular form, has been demonstrated as an inexpensive alternative to platinum for the electrochemical generation of hydrogen from water. Like many inorganic solids, the catalytic activity of MoS₂ is localized to rare edge sites, whereas the bulk material is relatively inert. The sulfur vacancy is recognized as a key defect type that can active the inert basal plane of MoS₂. The inventors of the present disclosure thus have researched to find an improved way of introducing sulfur vacancies into the inert basal plane of MoS₂ to improve its catalytic performance. As a result, they have found a defect-rich MoS₂ monolayer, and the method for manufacturing the same.

For the purposes of the present invention, the defect-rich MoS₂ layer is grown by a salt-assisted chemical vapor deposition method. Specifically, when forming the desired MoS₂ monolayer, a growth substrate (e.g., silicone) is pre-sprayed with a KCl solution about 0.5 to 3.0 M in concentration. Preferably, the KCl solution is about 2.0 M in concentration; more preferably, about 2.5 M in concentration. The growth substrate having been sprayed with the solution of KCl is placed in a reaction chamber that has been purged with an inert gas (e.g., N₂) to remove any residual oxygen.

A sulfur precursor and a molybdenum precursor are then introduced into the reaction chamber and reacted in a condition suitable for forming the desired MoS₂ monolayer on the growth substrate. Preferably, the sulfur precursor and the molybdenum precursor are reacted in the condition of about 800-840° C. under a carry gas for 10-20 mins to deposit a layer of MoS₂ on the growth substrate. Examples of the sulfur precursor suitable for use in the present method include, but are not limited to, sulfur powder, hydrogen sulfide (H₂S), dialkyl disulfide, dihalo disulfide and the like. In one preferred example, the sulfur precursor is sulfur powder. Examples of the molybdenum precursor suitable for use in the present method include, but are not limited to, sodium molybdate dihydrate (Na₂MoO₄·2H₂O), molybdenum hexafluoride (MoF₆), molybdenum hexachloride (MoCl₆) and molybdenum hexacarbonyl (Mo(CO)₆). In one preferred example, the molybdenum precursor is sodium molybdate dihydrate (Na₂MoO₄·2H₂O). Examples of the carry gas suitable for use in step (b) of the present method include, but are not limited to, argon (Ar), nitrogen (N₂) and the like. In one preferred example, the carry gas is Ar. According to preferred embodiments of the present disclosure, sulfur powder and sodium molybdate dihydrate are allowed to react in the reaction chamber at about 800-840° C. under 200 sccm Ar for 10-20 mins to deposit the layer of MoS₂ on the growth substrate (i.e., the MoS₂ growth substrate). The thus produced layer of MoS₂ has a vacancy density up to 3.35×10¹⁴/cm².

### 3. Use of the Vacancy-Rich MoS₂ Monolayer

The layer of MoS₂ produced by the present method may be transferred to a target substrate such as an electrode of a MoS₂-based microelectroactalysis cell (e.g., hydrogen fuel cell), for further use.

The transfer of the MoS₂ layer may be achieved by any method known in the related art, such as polymethyl-methacrylate (PMMA) assisted wet transfer, polyvinyl acetate (PVA)/PMMA wet transfer, and the like. According to embodiments of the present disclosure, the MoS₂ layer is transferred onto an electrode via PMMA assisted wet transfer process. In such scenario, the MoS₂ growth substrate described above in Section 2 of this paper is first spin-coated with a PMMA solution to form a PMMA/MoS₂ growth substrate. According to embodiments of the present disclosure, the PMMA solution is spin-coated onto the MoS₂ monolayer at a speed of 3,000 rpm for about 60 seconds to form the PMMA/MoS₂ growth substrate.

The PMMA/MoS₂ growth substrate is then immersed in an alkaline solution (e.g., KOH, NaOH, and the like) to detach the PMMA/MoS₂ structure from the growth substrate. In one example, the PMMA/MoS₂ growth substrate is immersed in 0.5 M KOH solution at 75° C. for about 1-15 mins to detach the PMMA/MoS₂ structure from the growth substrate. In another example, the PMMA/MoS₂ growth substrate is immersed in 0.5 M NaOH solution at 75° C. for about 1-15 mins to detach the PMMA/MoS₂ structure from the growth substrate.

The thus detached PMMA/MoS₂ structure is then transferred onto a target substrate (e.g., an electrode), thereby forming a PMMA/MoS₂ target substrate, which is then washed with one or more solvent to remove the PMMA layer thereby transferring the MoS₂ monolayer onto the target substrate. Examples of the solvent suitable for use in the present disclosure include, but are not limited to, acetone, isopropanol, ethanol and a combination thereof. According to one preferred embodiment of the present disclosure, the PMMA/MoS₂ target substrate is washed in sequence with acetone, isopropanol, and ethanol to remove the PMMA layer.

According to embodiments of the present disclosure, the growth substrate may be made of silicon dioxide or silicon, and the target substrate may be a transmission electron microscopy (TEM) grid or a semi-conducting substrate made of a material selected from the group consisting of glass, carbon fiber, carbon nanotube, carbon cloth, graphene, indium tin oxide, silicon, titanium dioxide and titanium metal. In one preferred example, the growth substrate is made of silicon, and the target substrate is an electrode made of carbon fiber.

Accordingly, the present disclosure also encompasses a MoS₂-based microelectroactalysis cell characterized in having a MoS₂ monolayer produced by the present method that serves as an electrocatalyst for hydrogen evolution reaction (HER). The MoS₂-based microelectroactalysis cell comprises in its structure, a working electrode, a counter electrode, a reference electrode, and an electrolyte; in which the working electrode, the counter electrode, or both independently comprises the present MoS₂ monolayer deposited thereon, and the MoS₂ monolayer has a vacancy density up to 3.35 ×10¹⁴/cm².

According to embodiments of the present disclosure, the MoS₂ monolayer acting as an electrocatalyst may be used to produce hydrogen from an aqueous solution (e.g., water). As used herein, the “aqueous solution” refers to a solution in which water is the solvent. The aqueous solution may contain various electrolytes and other compounds that are dissolved in water.

According to preferred embodiments of the present disclosure, the MoS₂ monolayer acts as an electrocatalyst exhibits exceptional catalytic activity based on microcell measurement, with an overpotential of about 158.8 mV (100 mA/cm²) and a Tafel slope of 54.3 mV/dec in 0.5 M H₂SO₄ electrolyte.

The present invention will now be described more specifically with reference to the following embodiments, which are provided for the purpose of demonstration rather than limitation. While they are typically of those that might be used, other procedures, methodologies, or techniques known to those skilled in the art may alternatively be used.

### EXAMPLES

### Materials and Methods

### Chemical Vapor Deposition (CVD) Growth of MoS₂

The MoS₂ flakes were grown on 300 nm SiO₂/Si substrate with the sprayed KCl at various concentrations including 0, 0.5, 1.0, 1.5, 2.0, 2.5, and 3.0 M. The growth of MoS₂ as adapted to a two-zone furnace with a 1-inch quartz tube under atmospheric pressure, using sulfur powder (20.0 mg) and Na₂MoO₄·2H₂O (5.5 mg) as the sulfur and molybdenum source, respectively. The MoS₂ as synthesized at 840° C. with a ramp rate of 20° C. min⁻¹ under 200 sccm Ar for 10 mins, and then cooled down to room temperature naturally. The growth condition of all samples was the same, except that the substrate was treated with different concentrations of KCl.

### Transfer of MoS₂

The MoS₂ was transferred by traditional PMMA-assisted wet transfer. A thin layer of PMMA film was spin-coated on the as-grown MoS₂ on SiO₂/SI at a speed of 3,000 rpm for 60 s. Then, the PMMA/MoS₂ film could be detached from SiO₂/Si substrate by emerging in 75° C. KOH solution for 1-15 mins. Then the film was washed using deionized water three times and then transferred to a device substrate or TEM grid. The PMMA could be washed clearly with acetone, isopropanol, and ethanol, respectively.

### Fabrication of MoS₂ Microdevice

The microdevices were fabricated by two rounds of electron beam lithography (EBL). First, a two-terminal device was fabricated by the standard EBL process. Then, constructed the Cr/Au electrode (5 nm/50 nm) by the lift-off of thermally evaporated metal films. At last, the PMMA encapsulation layer was opened in the channel of the two-terminal device to define the exposed area of MoS₂ for HER testing.

### Electrocatalysis Tests of MoS₂ Microdevice

An electrochemical work station (Gamry, Reference 600+) was used for the electrocatalysis tests. Based on the prepared MoS₂ microdevice, a modified three-electrode system was adapted for all tests, using a gold electrode as the working electrode, Ag/AgCl as the reference electrode, platinum as the counter electrode, and 0.5 m H₂SO₄ droplet as the electrolyte. Before each test, the electrolyte was first bubbled with Ar for 30 mins to remove dissolved oxygen. All the linear sweep voltammetry (LSV) tests were tested at a scan rate of 5 mV s⁻¹. Cyclic voltammetry curves exhibited a performance between 0.10-0.30 mV (vs reversible hydrogen electrode (RHE)) at the scan rate from 1 to 10 mV s⁻¹. Long-term durability was tested by chronoamperometry at 180 mV for 20 000 s. EIS measurements were carried out under a frequency range from 0.01 Hz to 100 KHz.

### Turnover Frequency Calculations

The turnover frequency (TOF) was calculated from the exchange current density normalized to the active surface of MoS₂ using the following relation:

$$TOF = \frac{Total number of {H}_{2} per second}{Total number of active sites per unit area} = \frac{j / ( n \times q )}{N}$$

Wherein j is the current density (A/cm²); n is 2 means 2 accounts of electrons involved per H₂; q=1.6×10⁻¹⁹; and N is the density of active sites (cm²).

### Material Characterizations

The MoS₂ flakes were observed through an optical microscope (ZEISS) under a bright field, dark field. The Topology of MoS₂ was characterized by atomic force microscopy employing an SI-DF3 silicon tip (Hitachi). The structure and optical properties were investigated by Raman and photoluminescence spectroscopy (Renishaw, inVia confocal) using the excitation wavelength of 514 nm. The atomic structure was performed by high-resolution TEM and STEM using a JEM-ARM200F TEM instrument with a CEOS spherical (Cs) aberration (probe) corrector. The aberration-corrected STEM was applied under 80 KV accelerating voltage to improve the image resolution and prevent beam damage. The elemental composition and chemical states were recorded by XPS spectra using a SPECS Phoibos 150 hemispherical electron energy analyzer with a base vacuum lower than 10-9 mbar.

### Example 1 Synthesis and Characterization of the Present Vacancy-Rich MoS₂ Film

### 1.1 Synthesis of the Present Vacancy-Rich MoS₂ Monolayers

The MoS₂ monolayers were synthesized in accordance with the procedures described in the “Materials and Methods” section, in which the substrate was pretreated by spraying with various concentrations of KCl solution ranging from 0 to 3.0 M prior to deposition of MoS₂ layer. The thus formed MoS₂ layer was then subjected to atomic force microscopy (AFM), scanning transmission electron microscopy (STEM), Raman and photoluminescence (PL) spectra analysis.

### 1.2 Characterization of the Present Vacancy-Rich MoS₂ Monolayers

### (i) AFM

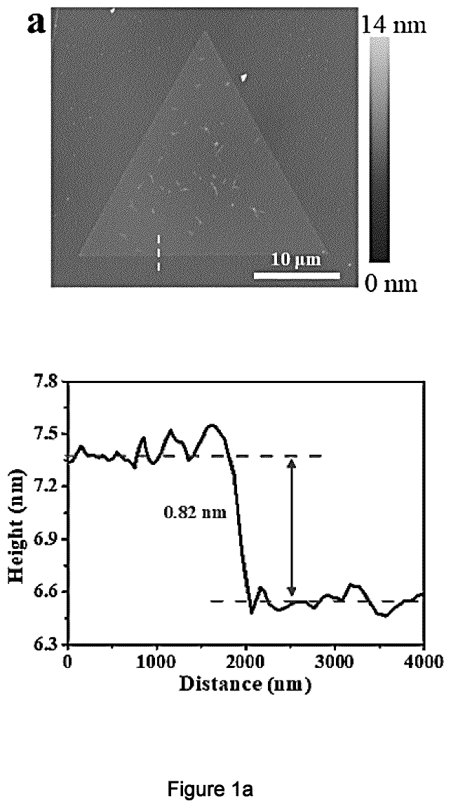

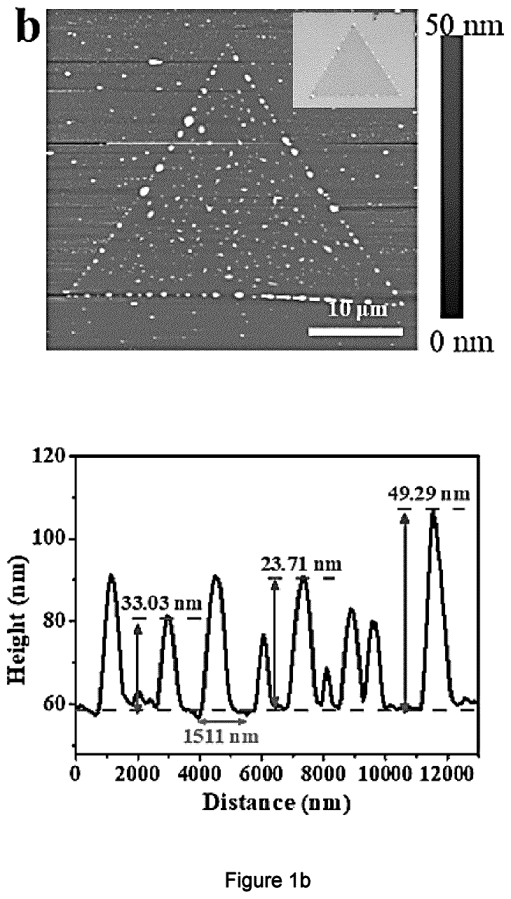

As expected, the MoS₂ layer grown without KCl (hereby termed as “MoS₂-0.0”) showed the typical triangular shape with a thickness of 0.82 nm (FIG. 1a); whereas catalytic particles were found on MoS₂ layer grown in the presence of 2.5 M KCl (hereby termed as “MoS₂-2.5 M”) (FIG. 1b). With the introduction of KCl, the density of catalytic particles increased and was predominantly distributed at corners or edges of MoS₂, which was observed by both AFM and optical microscopy (FIG. 1b). The same results were found for other concentration conditions of KCl (i.e., 0.5, 1.0, 1.5, 2.0 and 3.0 M). In sum, an increase in the concentration of KCl resulted in smaller-sized and higher-density catalyst particles.

### (ii) Raman and PL Spectra Analysis

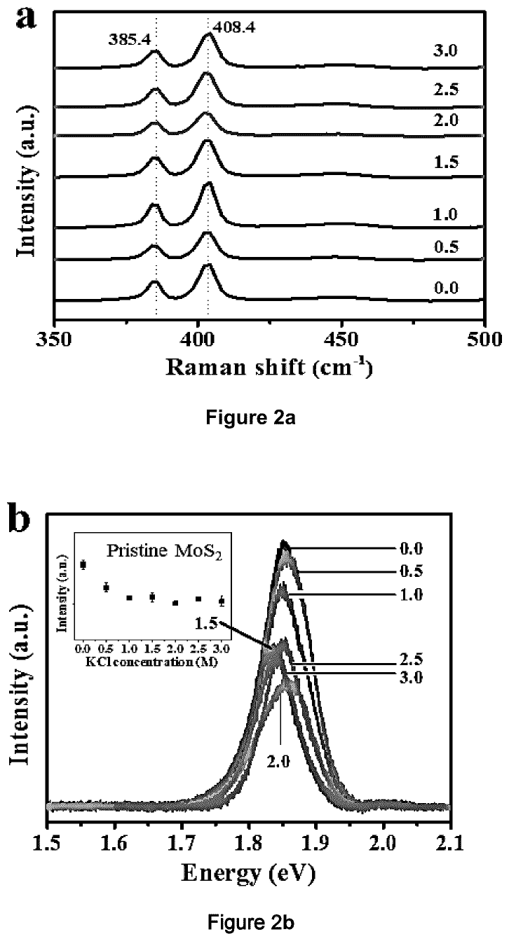

Raman and PL spectra were also used to investigate the structure of the MoS₂ monolayer on the basal plane and the catalytic particles. In Raman spectra, two prominent peaks of E_{2g}¹ (≈385 cm⁻¹) and A_{1g} (≈404 cm⁻¹) modes were observed on the basal plane, only slight downshift and redshift appear under higher KCl conditions, indicating the 2H phase of these samples was well maintained (FIG. 2a). As to the corresponding PL profiles, it was found that compared with the strong luminescence band (≈1.84 eV, A) of pristine MoS₂-0.0, the samples grown with KCl exhibited obvious redshift and lower intensity. The lowest PL strength was reached at 2.0 M KCl, which might be related to the p-doping contributed by metal-ion adsorption. Regarding the PL spectra, except for the dominant A peak, a weaker peak appeared near 2.0 eV, which might arise from the energy split of the valence band spin-orbital coupling of MoS₂ (FIG. 2b). Conversely, a gradual increase in the intensity and blueshift in position was observed in all bands with increasing KCl concentration up to 2.0 M, after which they remained stable upon further increases in concentration to 2.5 and 3.0 M. The observed PL quenching could be attributed to significant lattice distortions in the KCl-treated flakes and defect site saturation with trapped excitons.

(iii) STEM

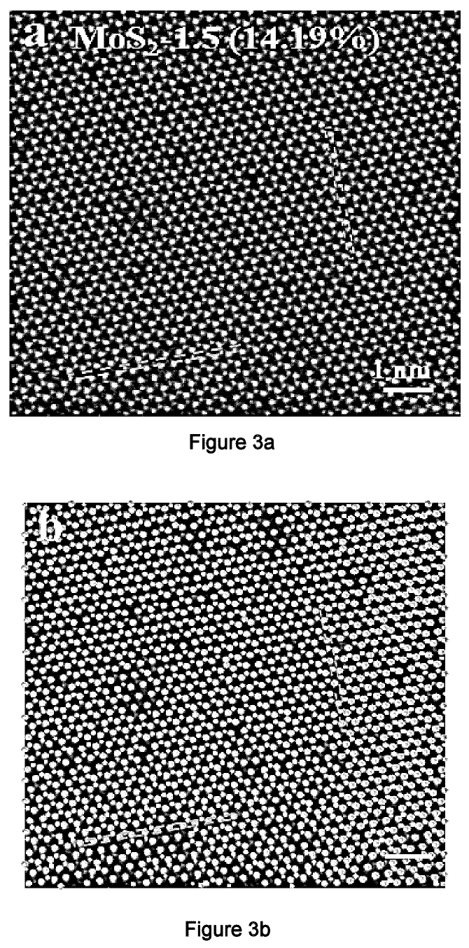

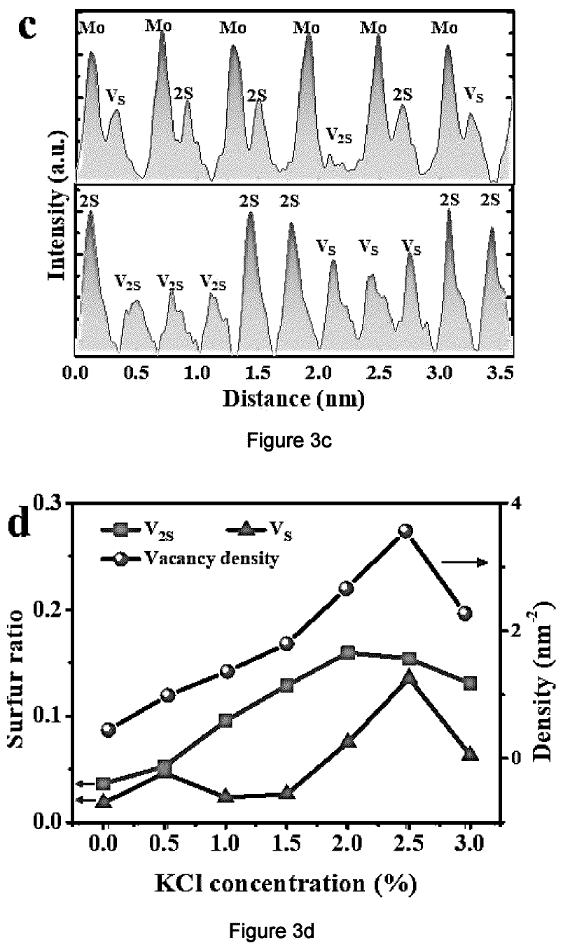

The atomic configurations of transferred MoS₂ with/without KCl were further investigated by STEM. Contrary to the near-perfect crystal structure of the pristine MoS₂-0.0, sample abundant vacancies were observed on the grown “MoS₂-1.5” (FIGS. 3a, 3b). The vacancy type and concentration in MoS₂ grown with KCl were carefully identified according to the atomic-scale high-angle annular dark-field (HAADF) images directly reflecting the atomic contrast. The intensity profile analysis on the STEM HAADF image indicated that the highest contrast was from Mo atoms, and Vₛ and V₂ₛ exhibited lowered intensity by ≈30% and 45%, respectively. Apparently, rich Vₛ and V₂ₛ vacancies existed in the basal plane of the MoS₂-1.5 sample (FIG. 3c)

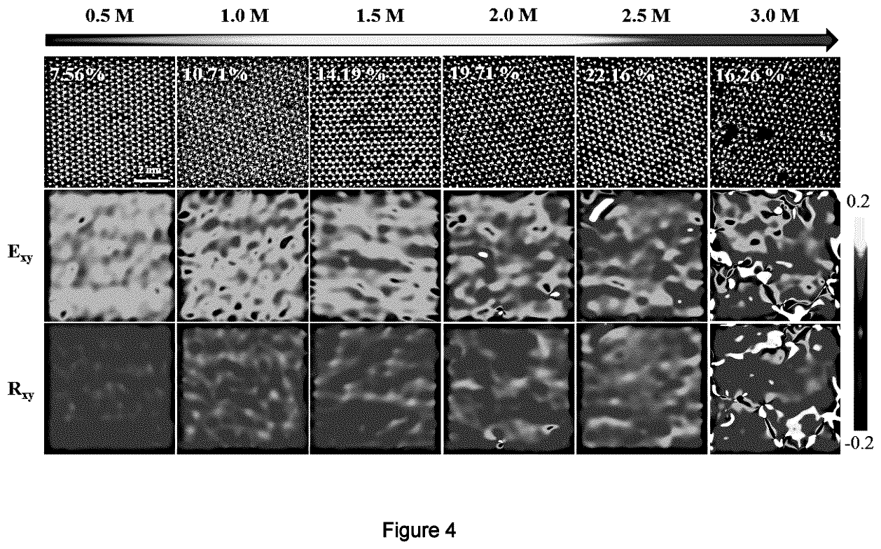

Similarly, the monolayer MoS₂ samples grown under different KCl concentrations were analyzed, and the sulfur vacancy densities were estimated by analyzing the atomic column contrast from HAADF-STEM images. Statistical analysis of more than 20 images was performed to represent larger and more varied sample areas, the results are depicted in FIG. 3d. It is found that the introduced KCl was related to the formation of defects on the basal plane of MoS₂, and the more KCl sprayed on the substrate, the more sulfur vacancies would be formed. As the sprayed KCl concentration increases from 0.0 to 2.5 M, the density of sulfur vacancies increased up to ≈29% (relative to the whole basal plane, ≈3.35×10¹⁴ cm⁻²) suggesting that the formation of sulfur vacancies might have reached saturation. Beyond 2.5 M KCl, partial S vacancies started to get stripped leading to larger defects that caused holes or cracks (FIG. 4), resulting in an expected reduction in S vacancies. In addition, such a decrease was also related to the adsorption behavior of K⁺.

The results confirmed that the inert basal plane of MoS₂ could be activated by the formation of sulfur vacancies and lattice strain induced by the introduction of salts, allowing for the simultaneous tuning of the density and activity of sulfur vacancy sites on the basal plane.

The lattice fluctuations and strain of a deposited MoS₂ may be quantified by the geometric phase analysis (GPA) technique, which directly reflects the lattice strain in a given area (FIG. 4). Accordingly, the present MoS₂ layer was subjected to strain-field mapping via analyzing HAADF-STEM images of the monolayer MoS₂ grown with different concentrations of KCl, as well as the corresponding GPA strain maps of E_{xy} (in-plane shear strain) and R_{xy} (in-plane lattice rotation).

It was found that the variation of E_{xy} and R_{xy} was enhanced with the increase of KCl concentration, and the strain value could reach up to 14%. The observed localized strain was consistent with the distribution of sulfur vacancies, causing significant variations in bond lengths and angles of the surrounding atoms. The generated lattice strain could activate the HER activity of basal plane.

### 1.3 Effect of PMMA-Assisted Transfer on the MoS₂ Monolayer

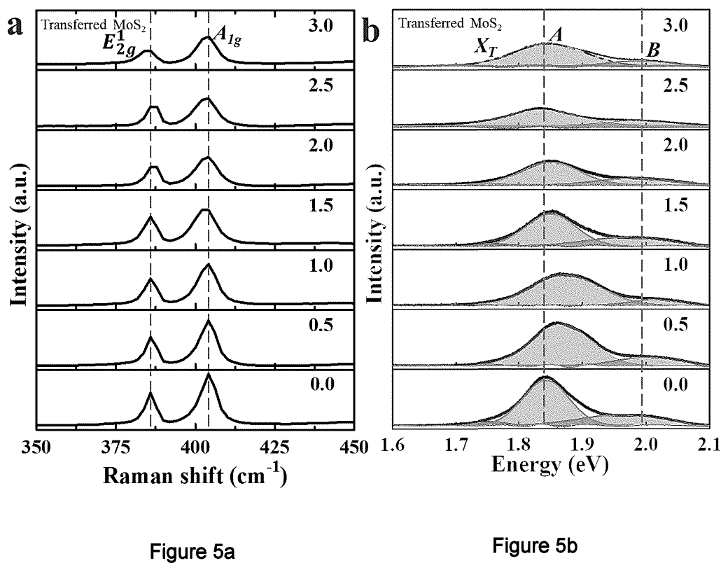

As the MoS₂ monolayer of Example 1.1 may be used as a conductive layer in a semi-conductive device or a catalyst in HER. Thus, in this example, the MoS₂ monolayer of Example 1.1 was transferred to a target substrate (e.g., a device substrate or a TEM grid) via PMMA-assisted transfer described in the section of “Materials and Methods” of this paper, and the transferred MoS₂ monolayer was then analyzed via Raman and PL spectroscopy. Results are depicted in FIGS. 5a, 5b.

Interestingly, as depicted in FIG. 5a, the Raman signal weakened significantly with increasing KCl concentration, which was markedly different from the essentially identical Raman strength observed prior to transfer. After transfer, it was found that the PL intensity was lowest under 2.5 M KCl, such reduction was dependent on the sulfur vacancies (FIG. 5b), which was also consistent with STEM results (all samples were tested after transfer).

### Example 2 Performance of the MoS₂-Based Microchemical Device in HER

In this example, a MoS₂ microchemical device for local electrocatalytic hydrogen evolution measurement was constructed in accordance with procedures described in the “Materials and Methods” section of this paper. Briefly, the synthesized MoS₂ monolayer was transferred onto a pre-patterned SiO₂/Si substrate and connected with gold contacts fabricated by e-beam lithography (EBL). Subsequently, a well-defined area was opened on the encapsulating layer of poly (methyl methacrylate) (PMMA), which served as the electrochemical window. The electrocatalytic performance of the as-grown MoS₂—KCl flakes was performed on a typical microreactor with a three-electrode system, where the gold electrode was the working electrode, Ag/AgCl as the reference electrode, platinum as counter electrode and 0.5 m H₂SO₄ droplet as the electrolyte.

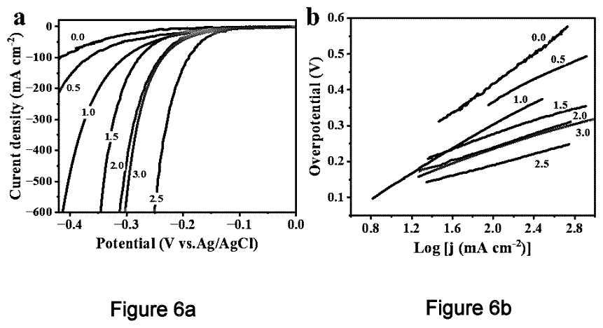

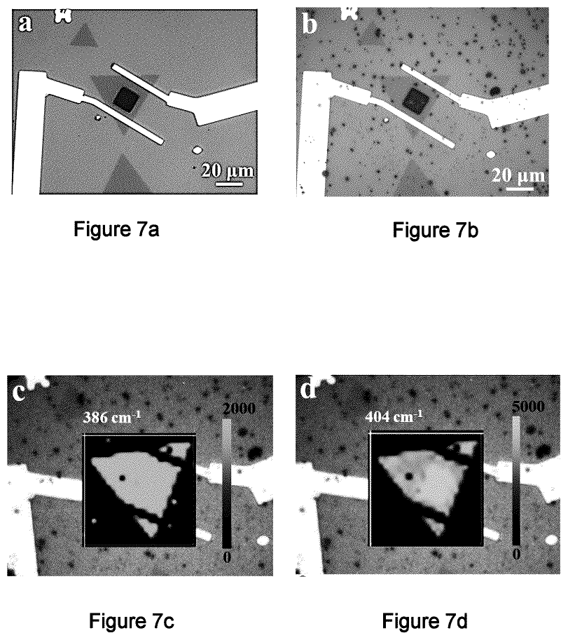

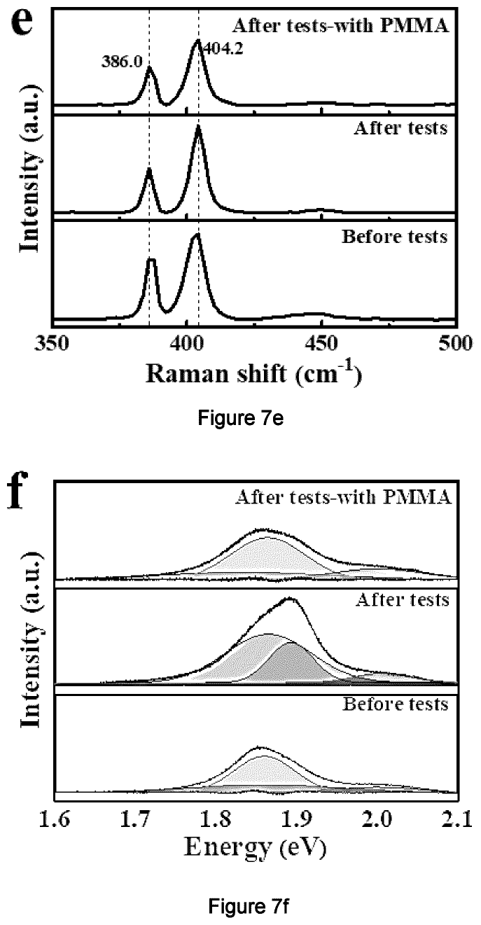

According to the polarization curves of the present vacancy-rich MoS₂ grown with different KCl, it was found that the HER performance improved with the introduction of KCl, which caused the increased in active sites (i.e., the sulfur vacancies). The pristine MoS₂-0.0 showed poor activity with an overpotential of 416.76 m V at 100 mA cm⁻², whereas the MoS₂ grown with KCl required a much smaller overpotential of 158.8±9 mV to reach the same current densities. Accordingly, the Tafel slope decreases from 211.95 to 54.3±12 mV dec⁻¹ when the introduced KCl increases to 2.5 M (FIGS. 6a, 6b). In addition, the electrochemical stability of the fabricated microdevice did not exhibit significant attenuation after 20,000 s with a fresh electrolyte. The device morphology remained intact after continuous operation, suggesting that the PMMA layer protects it well and only the exposed area contributed to the catalytic properties. Raman mapping image of the MoS₂ microdevice further revealed that the MoS₂ monolayer was quite homogeneous even after long cycling (FIGS. 7a-7e). The PL spectra in the test area became stronger and showed redshifts after the cycling, which might be ascribed to n-doping contributed by water moisture during electrochemical tests (FIG. 7f).

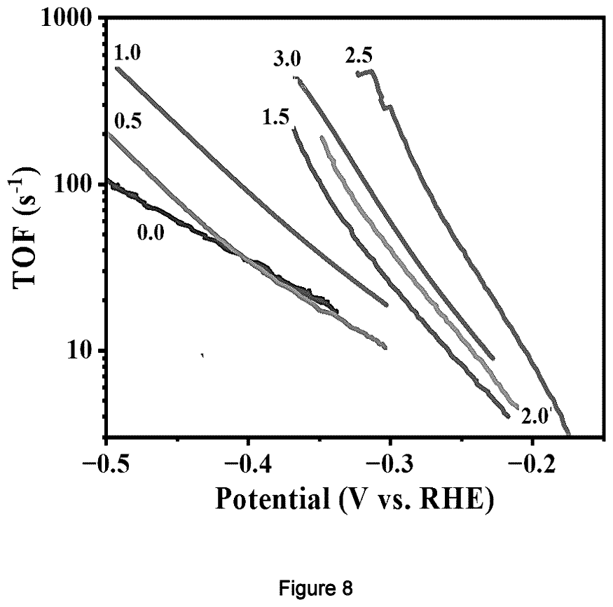

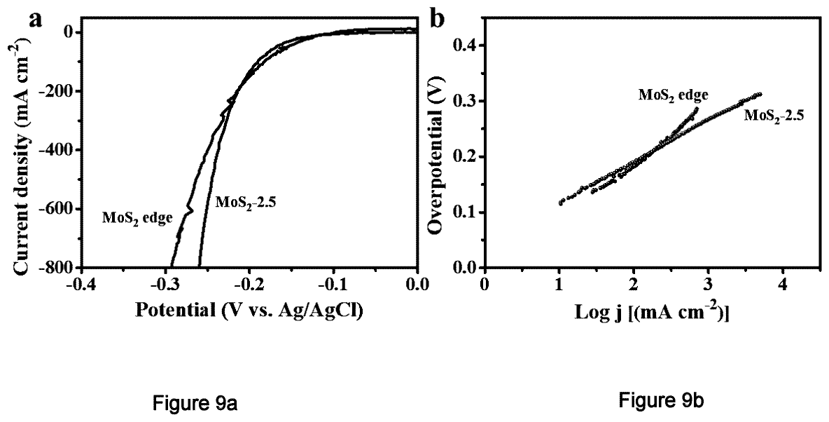

Given that the assembled microdevices possessed well-defined exposed surfaces, the number of individual active sites could be accurately determined. The turnover frequency (TOF) in each condition was extracted from the polarization curves. All TOF calculations consistently suggested that HER activity increased in a quasi-linear manner with the increase of treated KCl concentration, and the TOF for MoS₂-2.5 was more than an order of magnitude higher than that of MoS₂-0.0 in certain potential ranges (FIG. 8). The catalytic activity of a vacancy was not constant, that is, the activity of a vacancy could be enhanced or suppressed by controlling its concentration. Additionally, the overall performance was exceeding that of edge sites of MoS₂, the well-known intrinsic active sites in MoS₂ flakes (FIGS. 9a, 9b). The TOF of MoS₂-2.5 was calculated to be 1.4 S⁻¹ at zero potential, which was greater than most other MoS₂-based catalysts.

Taken together, the present disclosure confirmed that the basal plane of monolayer 2H MoS₂ could be activated to have enriched sulfur vacancies using a simple KCl-assisted CVD process, the thus produced vacancy-rich MoS₂ monolayer served as highly efficient catalytic sites for HER. Electrocatalysis microdevice fabricated using the present vacancy-rich MoSa exhibited a greatly enhanced HER activity compared to that constructed with the MoS₂ monolayer deposited without KCl.

It will be understood that the above description of embodiments is given by way of example only and that various modifications may be made by those with ordinary skill in the art. The above specification, examples and data provide a complete description of the structure and use of exemplary embodiments of the invention. Although various embodiments of the invention have been described above with a certain degree of particularity, or with reference to one or more individual embodiments, those with ordinary skill in the art could make numerous alterations to the disclosed embodiments without departing from the spirit or scope of the present disclosure.

What is claimed is:

1. A method of producing a defect-rich molybdenum disulfide (MoS₂) monolayer comprising vapor depositing the MoS₂ monolayer on a growth substrate in the presence of potassium chloride (KCl), wherein the MoS₂ film has a vacancy density up to 3.35×10¹⁴/cm².

2. The method of claim 1, wherein the MoS₂ monolayer is vapor deposited by,
(a) spraying a solution of the KCl on the growth substrate disposed in a reaction chamber; and
(b) allowing a sulfur precursor to react with a molybdenum precursor at about 800-900° C. in a flow of a carry gas for about 10-20 mins to deposit the MoS₂ monolayer on the growth substrate.

3. The method of claim 2, wherein the KCl solution has a concentration of about 0.5-3.0 M.

4. The method of claim 3, wherein the KCl solution is about 2.5 M in concentration.

5. The method of claim 2, wherein the carry gas is argon (Ar) or nitrogen (N₂).

6. The method of claim 5, wherein in step (b),
the sulfur precursor is selected from the group consisting of sulfur powder, hydrogen sulfide (H₂S), dialkyl disulfide and dihalo disulfide;
the molybdenum precursor is selected from the group consisting of sodium molybdate dihydrate (Na₂MoO₄·2H₂O), molybdenum hexafluoride (MoF₆), molybdenum hexachloride (MoCl₆) and molybdenum hexacarbonyl (Mo(CO)₆).

7. The method of claim 6, wherein in step (b), the MoS₂ monolayer is deposited by allowing the sulfur powder to react with the sodium molybdate dihydrate at about 840° C. under 200 sccm Ar for 10 min.

8. The method of claim 1, further comprising transferring the MoS₂ monolayer onto a target substrate by steps of:
(c) spin-coating a polymethyl-methacrylate (PMMA) solution on the MoS₂ monolayer to form a PMMA/MoS₂ growth substrate;
(d) immersing the PMMA/MoS₂ growth substrate in an alkaline solution to detach the PMMA/MoS₂ structure from the growth substrate;
(e) transferring the detached PMMA/MoS₂ structure onto the target substrate thereby forming a PMMA/MoS₂ target substrate; and
(f) washing the PMMA/MoS₂ target substrate with one or more solvent to remove the PMMA layer thereby transferring the MoS₂ monolayer onto the target substrate.

9. The method of claim 8, wherein in step (c), the PMMA solution is spin-coated onto the MoS₂ layer at a speed of 3,000 rpm for 60 seconds.

10. The method of claim 9, wherein in step (d), the alkaline solution is a solution of KOH or NaOH at a concentration of about 0.5 M.

11. The method of claim 10, wherein the PMMA/MoS₂ growth substrate is immersed in the KOH solution at 75° C. for about 1-15 minutes.

12. The method of claim 11, wherein in step (f), the solvent is selected from the group consisting of acetone, isopropanol, ethanol and a combination thereof.

13. The method of claim 12, wherein in step (f), the PMMA/MoS₂ target substrate is washed in sequence with acetone, isopropanol, and ethanol.

14. The method of claim 1, wherein
the growth substrate is made of silicon dioxide or silicon; and
the target substrate is a transmission electron microscopy (TEM) grid or a semi-conducting substrate.

15. The method of claim 14, wherein the semi-conducting substrate is made of a material selected from the group consisting of glass, carbon fiber, carbon nanotube, carbon cloth, graphene, indium tin oxide, silicon, titanium dioxide and titanium metal.

16. A MoS₂-based microelectroactalysis cell comprising a working electrode, a counter electrode, a reference electrode, and an electrolyte; wherein, the working electrode, the counter electrode or both independently comprises a MoS₂ monolayer coated thereon, in which the MoS₂ monolayer has a vacancy density up to 3.35×10¹⁴/cm².

17. The MoS₂-based microelectroactalysis cell of claim 16, wherein the MoS₂ monolayer is produced by a method comprising:
(a) spraying a KCl solution on a growth substrate disposed in a reaction chamber;
(b) allowing a sulfur precursor to react with a molybdenum precursor at about 800-900° C. in a flow of a carry gas for about 10-20 min to deposit a monolayer of MoS₂ on the growth substrate;
(c) spin-coating a polymethyl-methacrylate (PMMA) solution on the MoS₂ monolayer to form a PMMA/MoS₂ growth substrate;
(d) immersing the PMMA/MoS₂ growth substrate in an alkaline solution to detach the PMMA/MoS₂ structure from the growth substrate;
(e) transferring the detached PMMA/MoS₂ structure onto a target substrate thereby forming a PMMA/MoS₂ target substrate; and
(f) washing the PMMA/MoS₂ target substrate with one or more solvent to remove the PMMA layer thereby transferring the MoS₂ monolayer onto the target substrate;
wherein,
the target substrate is the working electrode, and/or the counter electrode of the MoS₂-based microelectroactalysis cell.

18. A method of producing hydrogen (H₂) from an aqueous solution comprising electrolyzing the aqueous solution in the MoS₂-based microelectroactalysis cell of claim 16.

19. The method of claim 18, wherein the aqueous solution is water.
